(19) United States
(12) Patent Application Publication
(10) Pub. No.: US 2025/0087596 A1
(43) Pub. Date: Mar. 13, 2025

(54) SEMICONDUCTOR PACKAGE

(71) Applicant: Samsung Electronics Co., Ltd., Suwon-si (KR)

(72) Inventor: Jaesun KIM, Suwon-si (KR)

(73) Assignee: Samsung Electronics Co., Ltd., Suwon-si (KR)

(21) Appl. No.: 18/641,782

(22) Filed: Apr. 22, 2024

(30) Foreign Application Priority Data
Sep. 13, 2023 (KR) 10-2023-0122073

(51) Int. Cl. H01L 23/552; H01L 23/00; H01L 23/31; H01L 23/36; H01L 23/498; H01L 23/538; H01L 25/065; H01L 25/10; H01Q 1/22

(52) U.S. Cl. CPC H01L 23/552; H01L 23/3128; H01L 23/36; H01L 23/49811; H01L 23/5383; H01L 23/5385; H01L 24/16; H01L 25/0655; H01L 25/105; H01Q 1/2283; H01L 24/08; H01L 2224/08225; H01L 2224/16227

(57) ABSTRACT

A semiconductor package may include a lower redistribution structure, conductive posts on an upper surface of the lower redistribution structure, a first semiconductor chip on the upper surface of the lower redistribution structure and separated from a conductive post in a first direction parallel to the upper surface of the lower redistribution structure, a radio frequency chip on the upper surface of the lower redistribution structure and separated from the first semiconductor chip in the first direction, a ground post between the first semiconductor chip and the radio frequency chip and configured to shield against an electromagnetic wave generated from the radio frequency chip, a molding layer covering the upper surface of the lower redistribution structure, and a ground layer in contact with an upper surface of the ground post. The molding layer may surround the conductive posts, first semiconductor chip, radio frequency chip, and ground post.

### CROSS-REFERENCE TO RELATED APPLICATION

This application is based on and claims priority under 35 U.S.C. § 119 to Korean Patent Application No. 10-2023-0122073, filed on Sep. 13, 2023 in the Korean Intellectual Property Office, the disclosure of which is incorporated by reference herein in its entirety.

### BACKGROUND

Inventive concepts relate to a semiconductor package.

Recently, along with the rapid development of the electronics industry and the demands of users, electronic devices may include a highly integrated semiconductor chip with a small size, multiple functions, and a large capacity. Therefore, a semiconductor package ensuring connection reliability with a highly integrated semiconductor chip having an increased number of connection terminals for input and output (I/O) has been proposed.

### SUMMARY

Inventive concepts provide a semiconductor package with improved operation reliability and/or electromagnetic shielding characteristics.

According to an embodiment of inventive concepts, a semiconductor package may include a lower redistribution structure; a plurality of conductive posts on an upper surface of the lower redistribution structure, the plurality of conductive posts including a conductive post; a first semiconductor chip on the upper surface of the lower redistribution structure, the first semiconductor chip being separated from the conductive post in a direction parallel to the upper surface of the lower redistribution structure; a radio frequency chip on the upper surface of the lower redistribution structure and separated from the first semiconductor chip in the direction parallel to the upper surface of the lower redistribution structure; a ground post between the first semiconductor chip and the radio frequency chip, the ground post configured to shield against an electromagnetic wave generated from the radio frequency chip; a molding layer covering the upper surface of the lower redistribution structure and surrounding the plurality of conductive posts, the first semiconductor chip, the radio frequency chip, and the ground post; and a ground layer on an upper surface of the molding layer and in contact with an upper surface of the ground post.

According to an embodiment of inventive concepts, a semiconductor package may include a lower redistribution structure; a plurality of conductive posts on an upper surface of the lower redistribution structure, the plurality of conductive posts including a conductive post; a first semiconductor chip on the upper surface of the lower redistribution structure and separated from the conductive post in a direction parallel to the upper surface of the lower redistribution structure; a radio frequency chip on the upper surface of the lower redistribution structure and separated from the first semiconductor chip in the direction parallel to the upper surface of the lower redistribution structure; a ground post between the first semiconductor chip and the radio frequency chip, the ground post configured to shield against an electromagnetic wave generated from the radio frequency chip; a molding layer covering the upper surface of the lower redistribution structure and surrounding the plurality of conductive posts, the first semiconductor chip, the radio frequency chip, and the ground post; a ground layer on an upper surface of the molding layer and in contact with an upper surface of the ground post; an upper redistribution structure including a plurality of upper vertical vias on the molding layer and a plurality of upper wiring layers in contact with at least one of the plurality of upper vertical vias; a ground wiring layer in contact with at least one of the plurality of upper vertical vias; and a heat spreader on an upper surface of the upper redistribution structure and in contact with the ground wiring layer. The ground layer may include a first ground layer and a second ground layer on an upper surface of the first ground layer. The ground layer may have a plurality of gas holes and a plurality of post holes penetrating the ground layer in a vertical direction. The plurality of post holes may correspond to upper surfaces of the plurality of conductive posts.

According to an embodiment of inventive concepts, a semiconductor package may include a lower redistribution structure; a plurality of conductive posts on an upper surface of the lower redistribution structure, the plurality of conductive posts including a conductive post; a first semiconductor chip on the upper surface of the lower redistribution structure and separated from the conductive post in a direction parallel to the upper surface of the lower redistribution structure; a radio frequency chip on the upper surface of the lower redistribution structure and separated from the first semiconductor chip in the direction parallel to the upper surface of the lower redistribution structure; a ground post between the first semiconductor chip and the radio frequency chip, the ground post configured to shield against an electromagnetic wave generated from the radio frequency chip; a molding layer covering the upper surface of the lower redistribution structure and surrounding the plurality of conductive posts, the first semiconductor chip, the radio frequency chip, and the ground post; a ground layer on an upper surface of the molding layer and in contact with an upper surface of the ground post; an upper redistribution structure including a plurality of upper vertical vias on the molding layer and a plurality of upper wiring layers in contact with at least one of the plurality of upper vertical vias; a ground wiring layer in contact with at least one of the plurality of upper vertical vias; a heat spreader on an upper surface of the upper redistribution structure and in contact with the ground wiring layer; a plurality of internal connection terminals on the upper surface of the upper redistribution structure; a second semiconductor chip in contact with the plurality of internal connection terminals and electrically connected to the first semiconductor chip; and a plurality of antennas on the upper surface of the upper redistribution structure and electrically connected to the radio frequency chip. The ground layer may include a first ground layer and a second ground layer on an upper surface of the first ground layer. The ground layer may have a plurality of gas holes and a plurality of post holes penetrating the ground layer in a vertical direction. The plurality of post holes may correspond to upper surfaces of the plurality of conductive posts. The ground post, the ground layer, the ground wiring layer, and the heat spreader may be electrically connected to each other. A thickness of the ground layer may be 10 μm or less. The first ground layer and the second ground layer may include a metal. A material of the first ground layer may be different from a material of the second ground layer.

### BRIEF DESCRIPTION OF THE DRAWINGS

Embodiments of inventive concepts will be more clearly understood from the following detailed description taken in conjunction with the accompanying drawings in which:

FIG. 1 is a cross-sectional view of a semiconductor package according to an embodiment;

FIG. 2 is a cross-sectional view of a semiconductor package according to another embodiment;

FIG. 3 is a top view of a semiconductor package according to an embodiment;

FIG. 4 is a top view of a semiconductor package according to an embodiment;

FIGS. 5 to 7 are top views of upper surfaces illustrating, in a process order, a method of manufacturing a semiconductor package, according to an embodiment;

FIGS. 8 to 19 are cross-sectional views illustrating, in a process order, a method of manufacturing a semiconductor package, according to an embodiment; and

FIG. 20 is a flowchart illustrating a process of generating a ground layer.

### DETAILED DESCRIPTION

Embodiments may allow various kinds of change or modification and various changes in form, and specific embodiments will be illustrated in drawings and described in detail in the specification. However, it should be understood that the presented embodiments do not limit the scope to a specific disclosing form. In addition, the embodiments described below are only illustrative, and various changes in form and details may be made therein.

The use of all illustrations or illustrative terms is simply to describe technical ideas in detail, and the scope of inventive concepts is not limited due to the illustrations or illustrative terms unless they are limited by claims.

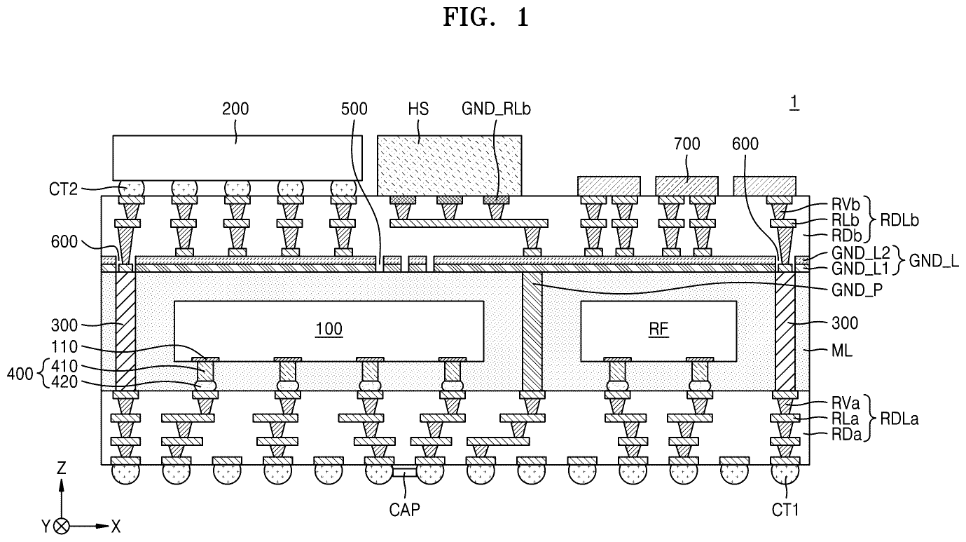

FIG. 1 is a cross-sectional view of a semiconductor package 1 according to an embodiment.

Referring to FIG. 1, the semiconductor package 1 may include a lower redistribution structure RDLa, a plurality of conductive posts 300 on the upper surface of the lower redistribution structure RDLa, a first semiconductor chip 100 on the upper surface of the lower redistribution structure RDLa and separated from a conductive post 300 in a first horizontal direction X and/or a second horizontal direction Y parallel to the upper surface of the lower redistribution structure RDLa, a radio frequency chip RF on the upper surface of the lower redistribution structure RDLa and separated from the first semiconductor chip 100 in the first horizontal direction X and/or the second horizontal direction Y parallel to the upper surface of the lower redistribution structure RDLa, and a ground post GND_P between the first semiconductor chip 100 and the radio frequency chip RF to shield against an electromagnetic wave generated from the radio frequency chip RF.

Hereinafter, unless specially defined, directions parallel to the upper surface of the lower redistribution structure RDLa and perpendicular to each other are defined as the first horizontal direction X and the second horizontal direction Y and a direction perpendicular to the upper surface of the lower redistribution structure RDLa is defined as a vertical direction Z. That is, the vertical direction Z is perpendicular to the first horizontal direction X and the second horizontal direction Y.

The semiconductor package 1 may further include a molding layer ML covering the upper surface of the lower redistribution structure RDLa and surrounding the plurality of conductive posts 300, the first semiconductor chip 100, the radio frequency chip RF, and the ground post GND_P and a ground layer GND_L on the upper surface of the molding layer ML and in contact with the upper surface of the ground post GND_P. In an embodiment, the molding layer ML may fill a separation space between the plurality of conductive posts 300. In an embodiment, the ground layer GND_L may include a first ground layer GND_L1 and a second ground layer GND_L2, but is not limited thereto and may include three or more layers. The ground layer GND_L may have a plurality of gas holes 500 penetrating at least partial regions of the ground layer GND_L in the vertical direction Z and a plurality of post holes 600 penetrating regions of the ground layer GND_L corresponding to the upper surfaces of the plurality of conductive posts 300 in the vertical direction Z, and the thicknesses and numbers of gas holes 500 and post holes 600 are not limited to the drawings.

The semiconductor package 1 may further include an upper redistribution structure RDLb on the molding layer ML, and the upper redistribution structure RDLb may include a plurality of upper vertical vias RVb, a plurality of upper wiring layers RLb each in contact with at least one of the plurality of upper vertical vias RVb, and a ground wiring layer GND_RLb in contact with at least one of the plurality of upper vertical vias RVb.

The semiconductor package 1 may further include a heat spreader HS on the upper surface of the upper redistribution structure RDLb and in contact with the ground wiring layer GND_RLb, a plurality of internal connection terminals CT2 on the upper surface of the upper redistribution structure RDLb, and a second semiconductor chip 200 in contact with the plurality of internal connection terminals CT2 and electrically connected to the first semiconductor chip 100. An upper wiring layer RLb and an upper vertical via RVb in contact with the upper wiring layer RLb may be above and in a post hole 600 provided in the ground layer GND_L, and the upper wiring layer RLb in the post hole 600 may be in direct contact with the conductive post 300 without interfering with the ground layer GND_L. A signal processed by the first semiconductor chip 100 may be transmitted to the second semiconductor chip 200 by being sequentially transferred through the lower redistribution structure RDLa, the conductive post 300, and the upper redistribution structure RDLb.

The semiconductor package 1 may further include a plurality of antennas 700 on the upper redistribution structure RDLb and electrically connected to the radio frequency chip RF. A signal processed by the radio frequency chip RF may be transmitted to the plurality of antennas 700 by being sequentially transferred through the lower redistribution structure RDLa, the conductive post 300, and the upper redistribution structure RDLb. The number of antennas 700, the thickness of each antenna 700, and the gap between antennas 700 are not limited to the drawings. Although FIG. 1 shows that the plurality of conductive posts 300 are arranged in a column at the left and right in the second horizontal direction Y, the plurality of conductive posts 300 may be arranged in a plurality of columns. The plurality of conductive posts 300 may be electrically connected to the lower redistribution structure RDLa. The plurality of conductive posts 300 may electrically connect the lower redistribution structure RDLa to the upper redistribution structure RDLb.

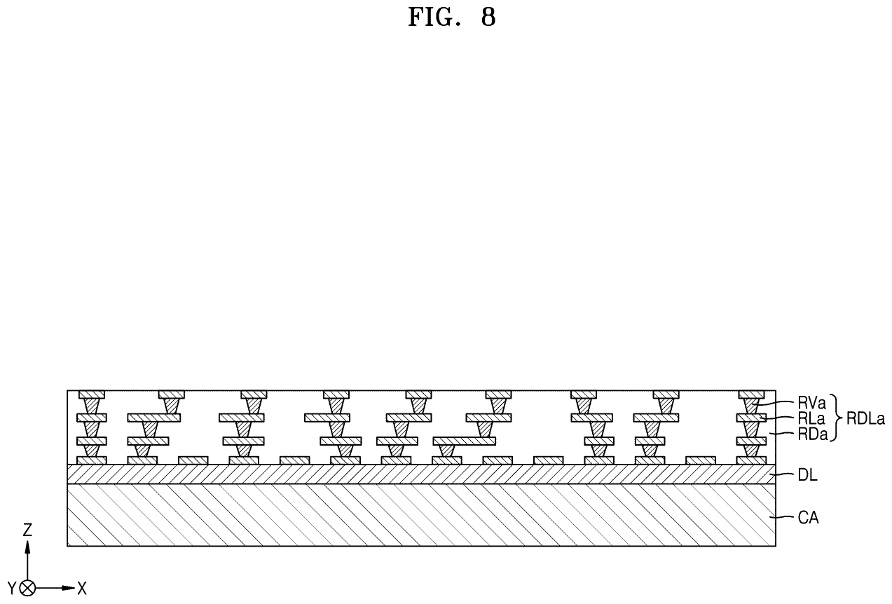

In some embodiments, the semiconductor package 1 may have a chip last structure in which the lower redistribution structure RDLa is formed on a carrier substrate CA (see FIG. 8) and then the first semiconductor chip 100 is mounted on the upper surface of the lower redistribution structure RDLa. In the chip last structure, the semiconductor package 1 may include a plurality of chip connection terminals 400 between the first semiconductor chip 100 and the lower redistribution structure RDLa and between the radio frequency chip RF and the lower redistribution structure RDLa and each of the plurality of chip connection terminals 400 may include a conductive cap 420 on the upper surface of the lower redistribution structure RDLa and electrically connected to the lower redistribution structure RDLa and a lower filler 410 on the upper surface of the conductive cap 420 and electrically connected to the conductive cap 420.

The first semiconductor chip 100 may include some of a plurality of semiconductor chip pads 110 at portions of the first semiconductor chip 100 in contact with some of a plurality of lower fillers 410, respectively, the other semiconductor chip pads 110 may be at portions of the radio frequency chip RF in contact with the other lower fillers 410, respectively, and the number, shape, and thickness of semiconductor chip pads 110 are not limited the drawings.

The first semiconductor chip 100 of the semiconductor package 1 may include an active surface and an inactive surface that is opposite to the active surface. In some embodiments, the first semiconductor chip 100 may be on the upper surface of the lower redistribution structure RDLa, such that the active surface of the first semiconductor chip 100 faces the lower redistribution structure RDLa, and the first semiconductor chip 100 may include some of the plurality of semiconductor chip pads 110 at the bottom thereof facing the lower redistribution structure RDLa in the vertical direction Z. Some of the plurality of semiconductor chip pads 110 may be electrically connected to individual devices on the active surface of the first semiconductor chip 100, and some of the plurality of semiconductor chip pads 110 may be electrically connected to the lower redistribution structure RDLa via some of the plurality of chip connection terminals 400, respectively.

The lower redistribution structure RDLa of the semiconductor package 1 may include a plurality of lower wiring layers RLa, a plurality of lower vertical vias RVa vertically connected to the plurality of lower wiring layers RLa, and a lower insulating layer RDa surrounding the plurality of lower wiring layers RLa and the plurality of lower vertical vias RVa and the upper redistribution structure RDLb may include the plurality of upper wiring layers RLb, the plurality of upper vertical vias RVb vertically connected to the plurality of upper wiring layers RLb, and an upper insulating layer RDb surrounding the plurality of upper wiring layers RLb and the plurality of upper vertical vias RVb.

The lower insulating layer RDa may include at least one material selected from among a phenol resin, an epoxy resin, and polyimide. The lower insulating layer RDa may include at least one material selected from among, for example, frame retardant 4 (FR-4), tetrafunctional epoxy, polyphenylene ether, epoxy/polyphenylene oxide, bismaleimide triazine (BT), Thermount, cyanate ester, polyimide, and liquid crystal polymer.

The lower vertical via RVa may include copper (Cu) or an alloy containing Cu, but is not limited thereto. For example, the lower vertical via RVa may include Cu, titanium (Ti), titanium tungsten (TiW), titanium nitride (TiN), tantalum (Ta), tantalum nitride (TaN), chromium (Cr), Cu stacked on Ti (Cu/Ti), or a structure in which Cu or an alloy containing Cu is stacked on a seed layer including Cu stacked on TiW (Cu/TiW), but is not limited thereto. In some embodiments, the lower vertical via RVa may be formed to cover the inner wall of a via through hole penetrating the lower insulating layer RDa and fill a portion of the via through hole.

The lower wiring layer RLa may include electrolytically deposited (ED) Cu foil, rolled-annealed (RA) Cu foil, a stainless steel foil, aluminum (Al) foil, ultra-thin Cu foil, sputtered Cu, a Cu alloy, or the like.

The upper vertical via RVb and the ground wiring layer GND_RLb may include Cu, an alloy containing Cu, and/or different materials. For example, the upper vertical via RVb and the ground wiring layer GND_RLb may include Cu, Ti, TiW, TiN, Ta, TaN, Cr, Cu/Ti, or a structure in which Cu or an alloy containing Cu is stacked on a seed layer including Cu/TiW, but is not limited thereto. In some embodiments, the upper vertical via RVb and the ground wiring layer GND_RLb may be formed to cover the inner wall of a via through hole penetrating the upper insulating layer RDb and fill a portion of the via through hole.

The upper wiring layer RLb may include ED Cu foil, RA Cu foil, stainless steel foil, Al foil, ultra-thin Cu foil, sputtered Cu, a Cu alloy, or the like.

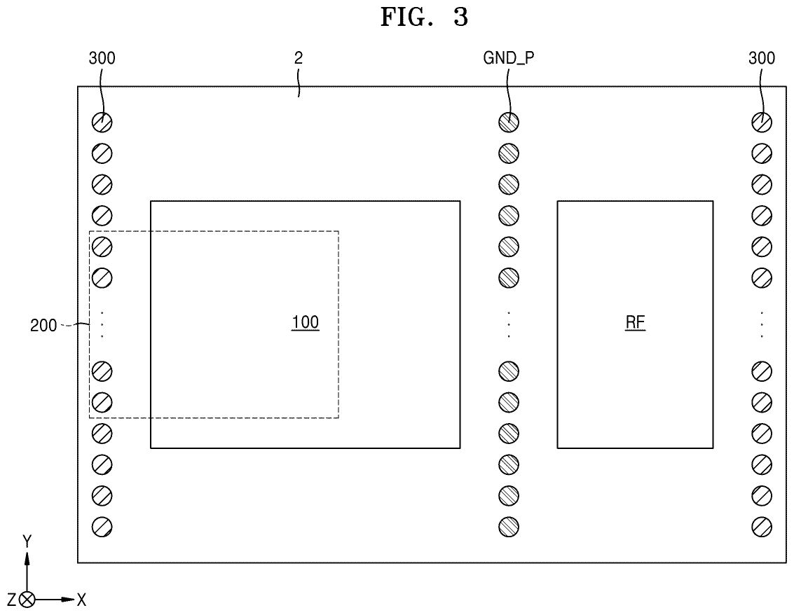

A substrate 2 (see FIG. 3) including the first semiconductor chip 100 may include a semiconductor material, e.g., silicon (Si) or germanium (Ge). Alternatively, the substrate 2 may include a compound semiconductor material, such as silicon carbide (SiC), gallium arsenide (GaAs), indium arsenide (InAs), or indium phosphide (InP). The substrate 2 (see FIG. 3) may include a conductive area, e.g., an impurity-doped well. The substrate 2 (see FIG. 3) may have various device isolation structures, such as a shallow trench isolation (STI) structure.

The first semiconductor chip 100 may include a conductive area, e.g., an impurity-doped well or an impurity-doped structure. A semiconductor device layer including individual devices may be provided on the active surface of the first semiconductor chip 100. The individual devices may include, for example, transistors. The individual devices may include microelectronic devices, e.g., a metal-oxide-semiconductor field effect transistor (MOSFET), a system large scale integration (LSI) chip, an image sensor, such as a complementary metal oxide semiconductor (CMOS) imaging sensor (CIS), a micro-electro-mechanical system (MEMS), an active device, a passive device, and the like.

The first semiconductor chip 100 may be a memory chip or a logic chip. The memory chip may include a volatile memory device, such as dynamic random access memory (DRAM) or static RAM (SRAM), or a nonvolatile memory chip, such as phase change RAM (PRAM), magnetoresistive RAM (MRAM), ferroelectric RAM (FeRAM), or resistive RAM (RRAM). The logic chip may include a central processing unit (CPU) chip, a graphics processing unit (GPU) chip, an application processor (AP) chip, or an application specific integrated circuit (ASIC) chip.

In some embodiments, the conductive post 300 and the ground post GND_P may include a metal, such as Cu, Al, tungsten (W), Ti, Ta, indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, but are not limited thereto. The conductive post 300 and the ground post GND_P may include different materials.

The semiconductor package 1 may further include a plurality of external connection terminals CT1 on the lower surface of the lower redistribution structure RDLa. The plurality of external connection terminals CT1 may be uniformly on at least partial regions of the lower surface of the lower redistribution structure RDLa. Accordingly, the plurality of external connection terminals CT1 may uniformly receive stress from the outside, thereby limiting and/or suppressing cracks which may occur in some external connection terminals CT1.

An external connection terminal CT1 may include, for example, a solder ball, a conductive paste, a ball grid array (BGA), a lead grid array (LGA), a pin grid array (PGA), or a combination thereof.

A capacitor structure CAP may be between at least some of the plurality of external connection terminals CT1.

The semiconductor package 1 may include the plurality of internal connection terminals CT2 on the lower surface of the second semiconductor chip 200. The plurality of internal connection terminals CT2 may be uniformly on at least partial regions of the lower surface of the second semiconductor chip 200. Accordingly, the plurality of internal connection terminals CT2 may uniformly receive stress from the outside, thereby limiting and/or suppressing cracks which may occur in some internal connection terminals CT2.

An internal connection terminal CT2 may include, for example, a solder ball, a conductive paste, a BGA, an LGA, a PGA, or a combination thereof.

In some embodiments, structurally, the lower vertical via RVa included in the lower redistribution structure RDLa may be formed to have a tapered shape with a width in the first horizontal direction X and/or a width in the second horizontal direction Y, which gradually increase (or increases) toward the lower surface of the first semiconductor chip 100. That is, the lower vertical via RVa of the lower redistribution structure RDLa may have a horizontal area gradually increasing toward the first semiconductor chip 100. In addition, structurally, the upper vertical via RVb included in the upper redistribution structure RDLb may be formed to have a tapered shape with a width in the first horizontal direction X and/or a width in the second horizontal direction Y, which gradually decrease (or decreases) toward the upper surface of the first semiconductor chip 100. That is, the upper vertical via RVb of the upper redistribution structure RDLb may have a horizontal area gradually decreasing toward the first semiconductor chip 100.

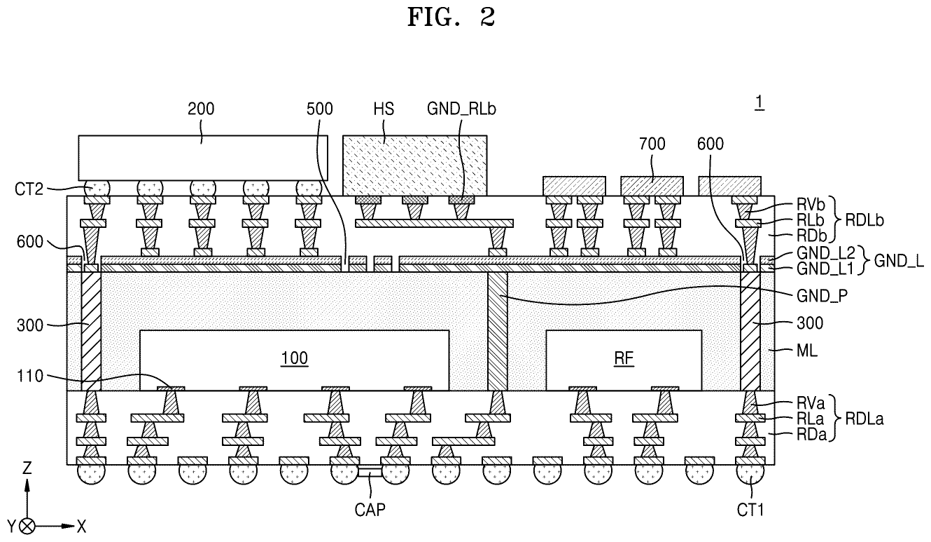

In some embodiments, the semiconductor package 1 may have a chip last structure in which the lower redistribution structure RDLa is formed on the carrier substrate CA (see FIG. 8) and then the first semiconductor chip 100 is mounted on the upper surface of the lower redistribution structure RDLa. However, the semiconductor package 1 is not limited thereto and may have a chip first structure as shown in FIG. 2. That is, the lower vertical via RVa of the lower redistribution structure RDLa may have a horizontal area varying toward the first semiconductor chip 100.

As shown in FIGS. 1 and 2, the lower redistribution structure RDLa may have the lower wiring layer RLa and the lower vertical via RVa formed in a three-layer structure and the upper redistribution structure RDLb may have the upper wiring layer RLb and the upper vertical via RVb formed in a two-layer structure, but the lower redistribution structure RDLa and the upper redistribution structure RDLb are not limited thereto. In addition, the thickness of the lower redistribution structure RDLa in the vertical direction Z may be greater than the thickness of the upper redistribution structure RDLb in the vertical direction Z, but is not limited thereto.

The second semiconductor chip 200 may be on the upper redistribution structure RDLb. The second semiconductor chip 200 may have an active surface and an inactive surface that is opposite to the active surface. The second semiconductor chip 200 may include, for example, Si. Alternatively, the substrate 2 may include a semiconductor element, such as Ge, or a compound semiconductor, such as SiC, GaAs, InAs, or InP. The second semiconductor chip 200 may include a conductive area, e.g., an impurity-doped well or an impurity-doped structure. A semiconductor device layer including individual devices may be provided on the active surface of the second semiconductor chip 200. The individual devices may include, for example, transistors. The individual devices may include microelectronic devices, e.g., a MOSFET, a system LSI chip, an image sensor, such as a CIS, a MEMS, an active device, a passive device, and the like.

The second semiconductor chip 200 may be a memory chip or a logic chip. The memory chip may include a volatile memory device, such as DRAM or SRAM, or a nonvolatile memory chip, such as PRAM, MRAM, FeRAM, or RRAM. The logic chip may include a CPU chip, a GPU chip, an AP chip, or an ASIC chip.

In some embodiments, the first semiconductor chip 100 may be a logic chip including a logic device and the second semiconductor chip 200 may be a memory chip. For example, the second semiconductor chip 200 may include, as a memory chip, a volatile memory chip and/or a nonvolatile memory chip. The first semiconductor chip 100 may be, as a logic chip, a CPU chip, a GPU chip, or an AP chip. That is, the second semiconductor chip 200 and the first semiconductor chip 100 may exchange the roles thereof.

In some embodiments, the second semiconductor chip 200 may be on the upper redistribution structure RDLb such that the active surface of the second semiconductor chip 200 faces the upper redistribution structure RDLb. In this case, the second semiconductor chip 200 may be electrically connected to the upper redistribution structure RDLb via the plurality of internal connection terminals CT2 formed between the second semiconductor chip 200 and the upper redistribution structure RDLb. That is, the second semiconductor chip 200 may be electrically connected to the lower redistribution structure RDLa via the plurality of internal connection terminals CT2, the upper redistribution structure RDLb, and the conductive post 300.

In some embodiments, the second semiconductor chip 200 may be on the upper redistribution structure RDLb such that the inactive surface of the second semiconductor chip 200 faces the upper redistribution structure RDLb. The second semiconductor chip 200 may be electrically connected to the upper redistribution structure RDLb via a conductive wire (not shown).

The ground layer GND_L may be formed on the molding layer ML after the molding layer ML is formed. The ground layer GND_L may include a plurality of layers, but for convenience of description, a description is made for a non-limiting example where the ground layer GND_L includes the first ground layer GND_L1 and the second ground layer GND_L2. According to an embodiment, the first ground layer GND_L1 and the second ground layer GND_L2 may be sequentially formed. After forming the first ground layer GND_L1, the second ground layer GND_L2 may be formed on the upper surface of the first ground layer GND_L1. As a forming method, not only physical vapor deposition (PVD) but also chemical vapor deposition CVD) may be used. The thickness of the ground layer GND_L may be 10 μm or less, but is not limited thereto. The thickness of each of the first ground layer GND_L1 and the second ground layer GND_L2 may be 10 μm or less. Each of the first ground layer GND_L1 and the second ground layer GND_L2 may include a metal, such as Cu, Al, W, Ti, Ta, In, Mo, Mn, Co, Sn, Ni, Mg, Re, Be, Ga, or Ru, or an alloy thereof, but is not limited thereto. The first ground layer GND_L1 and the second ground layer GND_L2 may include different materials.

The heat spreader HS may be in contact with and electrically connected to the ground wiring layer GND_RLb, and the ground wiring layer GND_RLb may be electrically connected to the ground layer GND_L via the upper vertical via RVb and the upper wiring layer RLb. In addition, the ground layer GND_L may be electrically connected to the ground post GND_P inside the molding layer ML, as described above. All of the heat spreader HS, the ground wiring layer GND_RLb, the ground layer GND_L, and the ground post GND_P electrically connected to each other may be grounded and thus shield against an electromagnetic wave generated by the radio frequency chip RF. By shielding against the electromagnetic wave, an influence interfered during a process of operating other components in the semiconductor package 1 due to the electromagnetic wave may be limited and/or prevented.

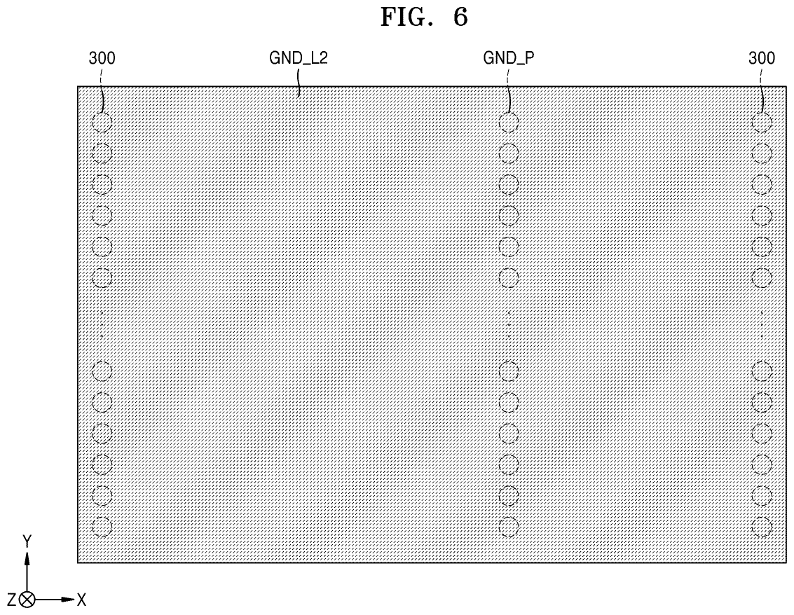

The ground layer GND_L may be removed through an etching process on a partial region or a region corresponding to the conductive post 300 after deposition is completed. This is described in detail after a description with reference to FIG. 6.

FIG. 2 is a cross-sectional view of the semiconductor package 1 according to another embodiment. Most components included in the semiconductor package 1 described below and materials forming the components are the same, substantially the same as or similar to those described above with reference to FIG. 1. Therefore, for convenience of description, a description of the structure of FIG. 2 is mainly made with differences from the semiconductor package 1 of FIG. 1.

Referring to FIG. 2, the semiconductor package 1 may have a chip first structure. Particularly, the semiconductor package 1 may have a structure in which the first semiconductor chip 100 is mounted on the carrier substrate CA (see FIG. 8) and then the lower redistribution structure RDLa is formed on the first semiconductor chip 100. The lower redistribution structure RDLa of the semiconductor package 1 may include the lower wiring layer RLa, the lower vertical via RVa vertically connected to the lower wiring layer RLa, and the lower insulating layer RDa surrounding the lower wiring layer RLa and the lower vertical via RVa.

In some embodiments, structurally, the lower vertical via RVa included in the lower redistribution structure RDLa may be formed to have a width in the first horizontal direction X and/or a width in the second horizontal direction Y, which gradually decrease (or decreases) toward the lower surface of the first semiconductor chip 100. That is, the lower vertical via RVa of the lower redistribution structure RDLa may have a horizontal area gradually decreasing toward the first semiconductor chip 100.

The first semiconductor chip 100 of the semiconductor package 1 may be on the lower redistribution structure RDLa. Each of the plurality of semiconductor chip pads 110 at portions where the active surface of the first semiconductor chip 100 and the radio frequency chip RF are in contact with the lower redistribution structure RDLa may be in direct contact with the lower redistribution structure RDLa.

FIG. 3 is a top view of a semiconductor package according to an embodiment.

Referring to FIG. 3, in an embodiment, the upper surface of the lower redistribution structure RDLa on the substrate 2 is shown. The first semiconductor chip 100 may be on a partial region of the substrate 2, and the radio frequency chip RF may be separated from the first semiconductor chip 100 in the first horizontal direction X. The shape of the first semiconductor chip 100 and the shape of the radio frequency chip RF are not limited to the shapes shown in FIG. 3. A plurality of ground posts GND_P may be between the first semiconductor chip 100 and the radio frequency chip RF. Although FIG. 3 shows that the plurality of ground posts GND_P are arranged in a column, the number of ground posts GND_P is not limited thereto and the plurality of ground posts GND_P may be arranged in a plurality of columns. The plurality of conductive posts 300 may be at one side of the first semiconductor chip 100 and one side of the radio frequency chip RF. Although FIG. 3 shows that the plurality of conductive posts 300 are arranged in two columns, the number of conductive posts 300 is not limited thereto and the plurality of conductive posts 300 may be arranged in a plurality of columns.

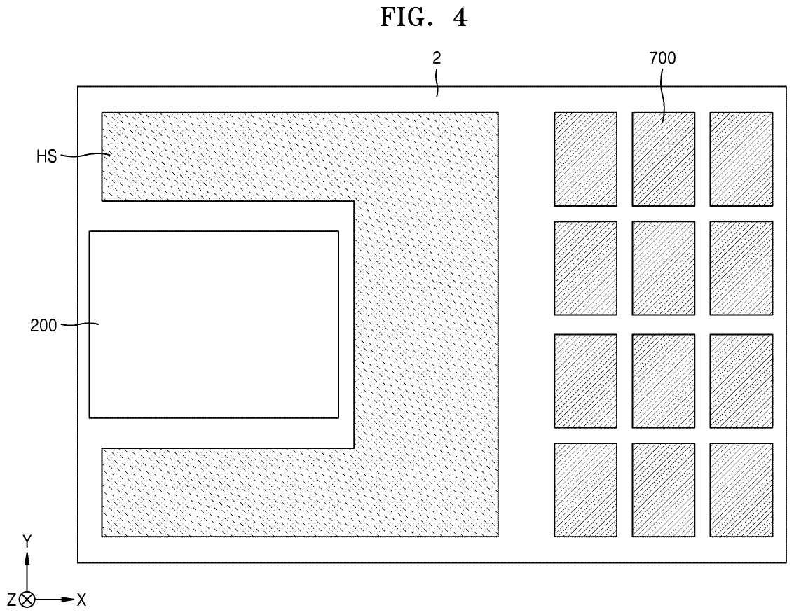

FIG. 4 is a top view of a semiconductor package according to an embodiment.

Referring to FIG. 4, in an embodiment, the upper surface of the molding layer ML (see FIG. 1) on the substrate 2 is shown. The second semiconductor chip 200 may be on a partial region of the substrate 2, and the heat spreader HS may be separated from the second semiconductor chip 200 and have a U shape turned counterclockwise. The second semiconductor chip 200 shown in FIG. 4 may be at the same location as the second semiconductor chip 200 indicated by the dashed line in FIG. 3.

The plurality of antennas 700 may be separated from the heat spreader HS in the first horizontal direction X. Although FIG. 4 shows that the plurality of antennas 700 are arranged in three columns, the plurality of antennas 700 are not limited thereto and the shape of the plurality of antennas 700 is not limited to the shape shown in FIG. 4.

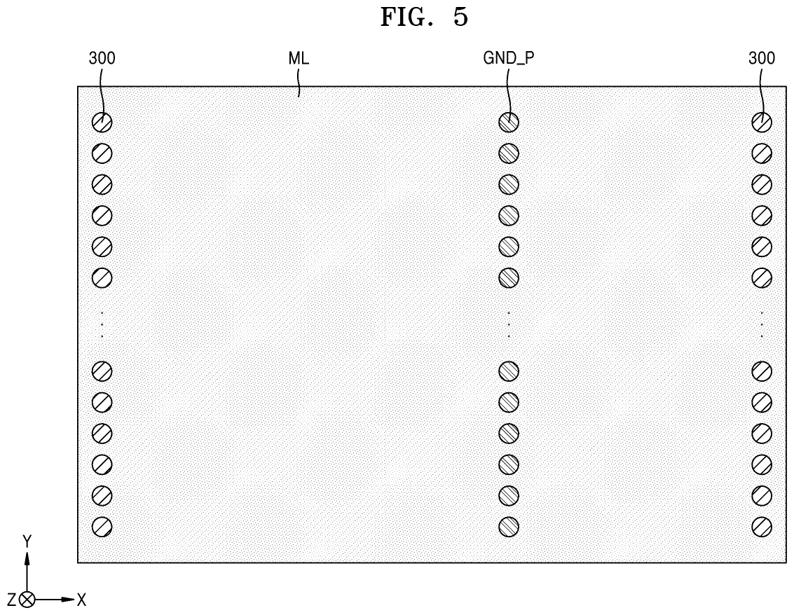

FIGS. 5 to 7 are top views of upper surfaces illustrating, in a process order, a method of manufacturing a semiconductor package, according to an embodiment.

Referring to FIG. 5, the molding layer ML may be formed to surround the first semiconductor chip 100, the radio frequency chip RF, the plurality of conductive posts 300, and the plurality of ground posts GND_P shown in FIG. 3. The height of the molding layer ML may be the same as the height of each of the plurality of conductive posts 300 and the plurality of ground posts GND_P, and as shown in FIG. 5, in a top view, the upper surface of each of the plurality of conductive posts 300 and the plurality of ground posts GND_P may be exposed.

Referring to FIG. 6, after forming the molding layer ML as shown in FIG. 5, the ground layer GND_L (see FIG. 1) may be formed on the upper surface of the molding layer ML and in more detail, the first ground layer GND_L1 (see FIG. 1) and the second ground layer GND_L2 on the upper surface of the first ground layer GND_L1 (see FIG. 1) may be formed. The first ground layer GND_L1 (see FIG. 1) and the second ground layer GND_L2 may cover the upper surfaces of the plurality of conductive posts 300 and the plurality of ground posts GND_P in a deposition process.

Referring to FG. 7, partial regions of the ground layer GND_L (see FIG. 1) may be removed by etching. In an embodiment, regions of the ground layer GND_L (see FIG. 1) corresponding to the upper surface of the plurality of conductive posts 300 may be removed to form the plurality of post holes 600 (see FIG. 1) penetrated in the vertical direction Z. By forming the plurality of post holes 600 (see FIG. 1) in the ground layer GND_L (see FIG. 1), as shown in FIG. 1, at least one upper wiring layer RLb (see FIG. 1) may be in contact with the conductive post 300.

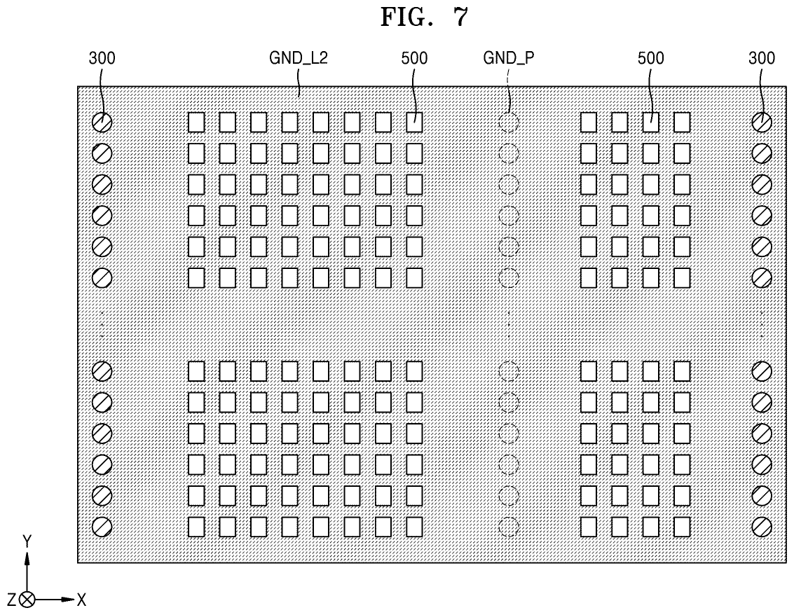

In an embodiment, the plurality of gas holes 500 may be formed by penetrating partial regions of the ground layer GND_L (see FIG. 1) in the vertical direction Z. Although FIG. 7 shows eight columns of gas holes 500 and four columns of gas holes 500, the plurality of gas holes 500 are not limited thereto and the shape and size of a gas hole 500 are not limited to those shown in FIG. 7. By forming the plurality of gas holes 500, the molding layer ML may be exposed in regions corresponding to the plurality of gas holes 500.

Although the upper surfaces of the plurality of conductive posts 300 may be exposed to the outside when the plurality of post holes 600 (see FIG. 1) are formed, the upper surfaces of the plurality of ground posts GND_P may not be exposed because regions of the ground layer GND_L (see FIG. 1) corresponding to the upper surfaces of the plurality of ground posts GND_P are not removed.

FIGS. 8 to 19 are cross-sectional views illustrating, in a process order, a method of manufacturing a semiconductor package, according to an embodiment.

Referring to FIG. 8, an adhesive insulating layer DL may be attached onto the carrier substrate CA and the lower redistribution structure RDLa may be formed on the adhesive insulating layer DL.

The carrier substrate CA may include, for example, glass, a semiconductor, ceramic, plastic, or Al oxide. The adhesive insulating layer DL may include a random material which may fix to the lower redistribution structure RDLa. The adhesive insulating layer DL may include, for example, an adhesive tape of which the adhesive force is weakened by heat treatment or laser irradiation. In some embodiments, the lower redistribution structure RDLa may be formed on the adhesive insulating layer DL by a plating process or a deposition process.

The lower redistribution structure RDLa may include the lower wiring layer RLa, the lower vertical via RVa vertically connected to the lower wiring layer RLa, and the lower insulating layer RDa surrounding the lower wiring layer RLa and the lower vertical via RVa.

As shown in FIGS. 8 to 19, in the method of manufacturing a semiconductor package of a chip last structure, the lower vertical via RVa may have a horizontal width increasing away from the carrier substrate CA. For example, the lower wiring layer RLa and the lower vertical via RVa in contact with the lower surface of the lower wiring layer RLa may be formed together to form one body. However, the lower vertical via RVa is not limited thereto, and in the method of manufacturing a semiconductor package of a chip last structure, the lower vertical via RVa may have a horizontal width decreasing away from the carrier substrate CA.

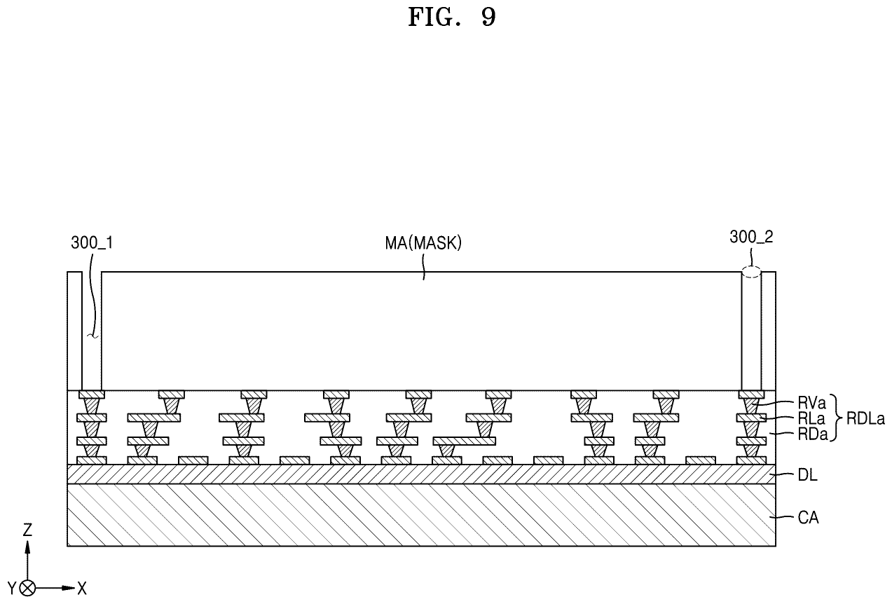

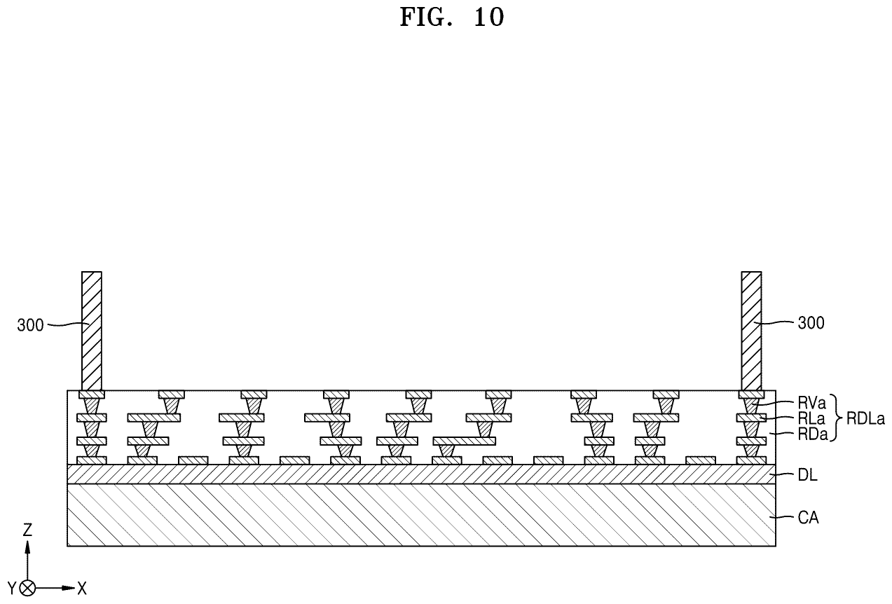

Referring to FIGS. 9 and 10, the conductive post 300 may be formed on the lower redistribution structure RDLa. A sacrificial insulating layer as a mask MA may be formed on the lower redistribution structure RDLa, and a plurality of vias penetrating the mask MA may be formed. Each of the plurality of vias may include a conductive post generation portion 300_1 that is a space in which the conductive post 300 is to be formed and a plating process region 300_2, which is at the top of the conductive post generation portion 300_1 and into which a plating material is to be inserted. The conductive post generation portion 300_1 may have a constant horizontal width, but is not limited thereto and may have a horizontal width decreasing toward the lower redistribution structure RDLa.

Next, in a plating process, the plurality of conductive posts 300 may be formed in the shape of the conductive post generation portion 300_1 by filling the plating process region 300_2 with a conductive material. The plurality of conductive posts 300 may be in direct contact with and electrically connected to the lower redistribution structure RDLa.

In some embodiments, because the conductive post generation portion 300_1 perfectly penetrates the mask MA that is a sacrificial insulating layer, the heights of the plurality of conductive posts 300 in the vertical direction Z may be the same as each other. For example, the upper surfaces of the plurality of conductive posts 300 may be coplanar with each other.

After forming the plurality of conductive posts 300, the mask MA as a sacrificial insulating layer may be removed.

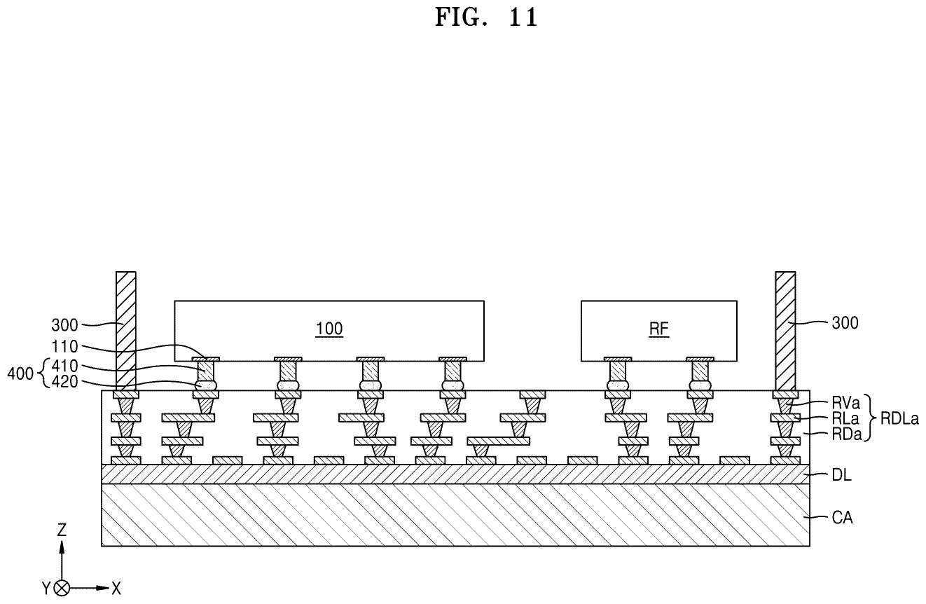

Referring to FIG. 11, the first semiconductor chip 100 may be attached to a region of the lower redistribution structure RDLa. The radio frequency chip RF may be attached to a region of the lower redistribution structure RDLa so as to be separated from the first semiconductor chip 100. Although FIG. 11 shows that the first semiconductor chip 100 and the radio frequency chip RF are simultaneously attached onto the lower redistribution structure RDLa in a flip chip mount process, the first semiconductor chip 100 and the radio frequency chip RF may be sequentially mounted on the lower redistribution structure RDLa.

In some embodiments, the first semiconductor chip 100 may be electrically connected to the lower redistribution structure RDLa via some of the plurality of chip connection terminals 400 respectively connected to some of the plurality of semiconductor chip pads 110 formed on the active surface of the first semiconductor chip 100.

In some embodiments, the radio frequency chip RF may be electrically connected to the lower redistribution structure RDLa via the other chip connection terminals 400 respectively connected to the other semiconductor chip pads 110 formed on the radio frequency chip RF. In more detail, the lower filler 410 may be in contact with the lower surface of the semiconductor chip pad 110 and electrically connected to the lower redistribution structure RDLa via the conductive cap 420 between the lower filler 410 and the lower redistribution structure RDLa.

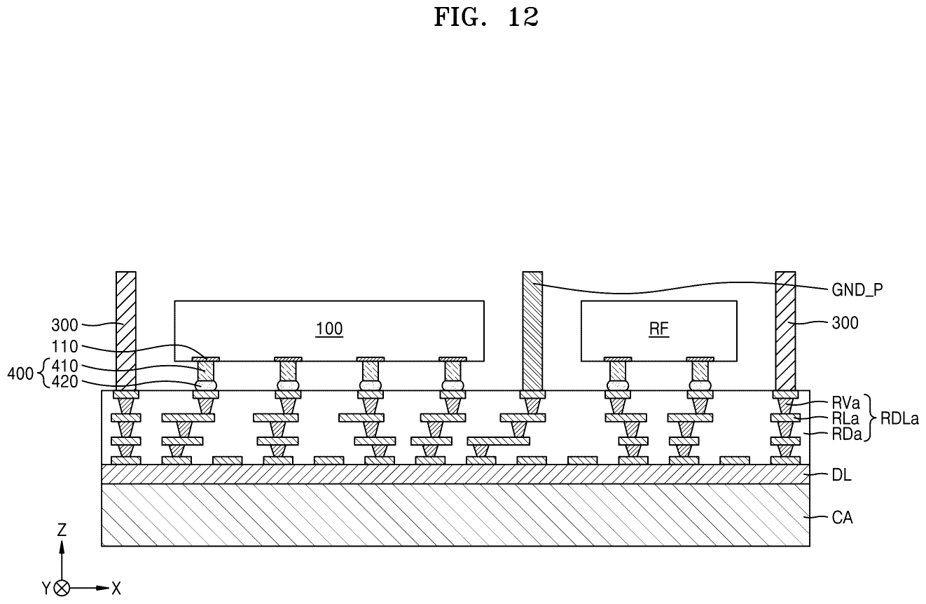

Referring to FIG. 12, the ground post GND_P may be attached to the lower redistribution structure RDLa between the first semiconductor chip 100 and the radio frequency chip RF. The ground post GND_P may be separated from the first semiconductor chip 100 in the first horizontal direction X, and the radio frequency chip RF may be separated from the ground post GND_P in the first horizontal direction X. By arranging the ground post GND_P between the radio frequency chip RF and the first semiconductor chip 100, an electromagnetic wave generated during an operation process of the radio frequency chip RF may be shielded by the ground post GND_P and thus may not interfere in an operation of the first semiconductor chip 100.

The height of the ground post GND_P may be greater than or equal to the height of the conductive post 300, and the level of the upper surface of the ground post GND_P in the vertical direction Z may be higher than or equal to the level of the radio frequency chip RF in the vertical direction Z. However, inventive concepts is not limited thereto.

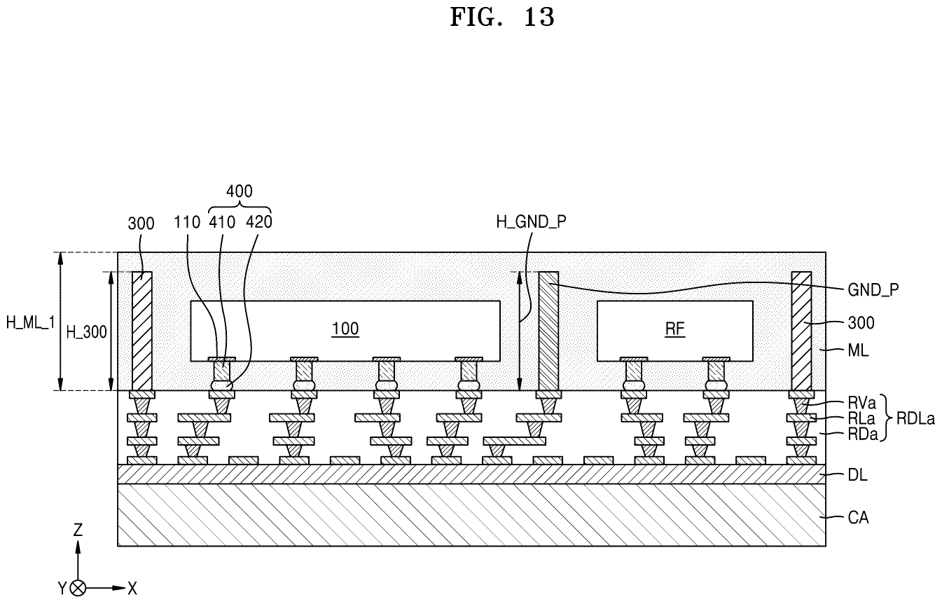

Referring to FIG. 13, the molding layer ML may be formed to surround the first semiconductor chip 100, the plurality of conductive posts 300, the radio frequency chip RF, and the ground post GND_P.

In some embodiments, the molding layer ML may be formed thick to fully cover the first semiconductor chip 100, the plurality of conductive posts 300, the radio frequency chip RF, and the ground post GND_P. Therefore, a height H_ML_1 of the molding layer ML in the vertical direction Z may be greater than a height H_300 of the plurality of conductive posts 300 in the vertical direction Z and a height H_GND_P of the ground post GND_P in the vertical direction Z, but is not limited thereto.

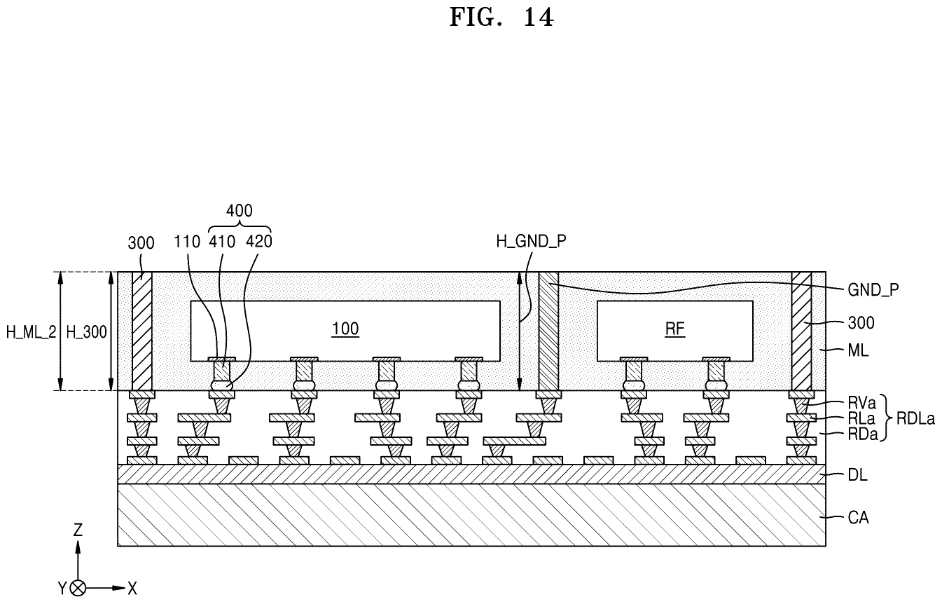

Referring to FIG. 14, after forming the molding layer ML, an upper portion of the molding layer ML may be removed through etching by a grinder such that the upper surfaces of the plurality of conductive posts 300 and the upper surface of the ground post GND_P are exposed to the outside.

In some embodiments, a height H_ML_2 of the molding layer ML after the etching may be the same as or substantially the same as the height H_300 of the plurality of conductive posts 300 in the vertical direction Z after the etching and the height H_GND_P of the ground post GND_P in the vertical direction Z after the etching.

In some embodiments, the upper surface of the molding layer ML may be coplanar with the upper surface of the conductive post 300, and the upper surface of the ground post GND_P.

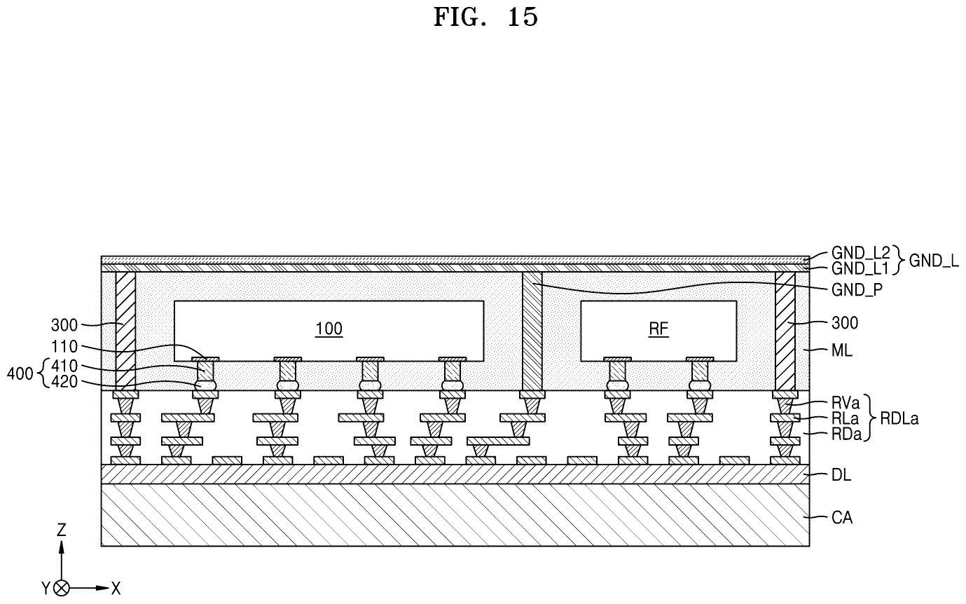

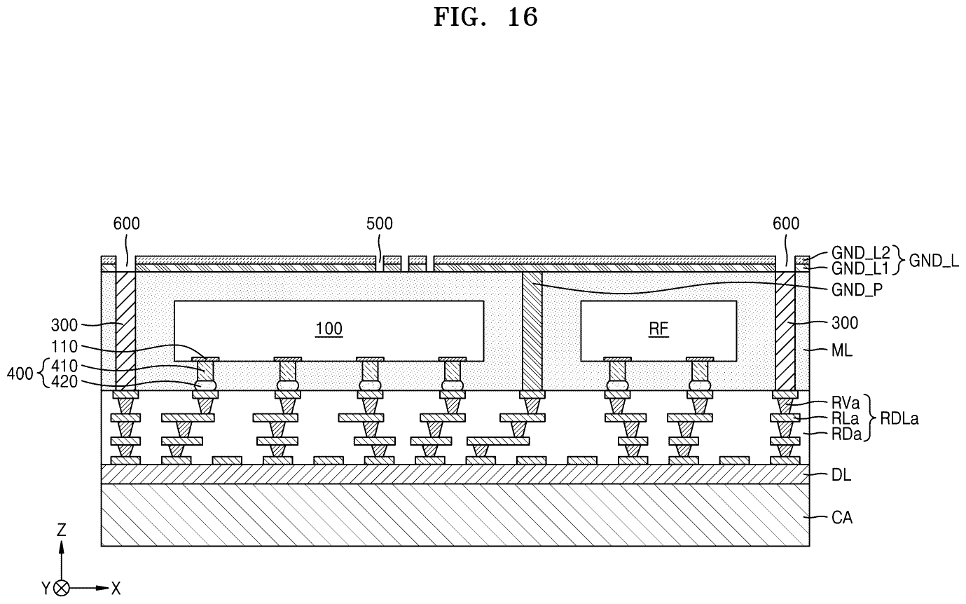

Referring to FIGS. 15 and 16, the ground layer GND_L may be formed on the upper surface of the molding layer ML. In more detail, the first ground layer GND_L1 may be formed on the upper surface of the molding layer ML and the second ground layer GND_L2 may be formed on the upper surface of the first ground layer GND_L1. In the present embodiment, the ground layer GND_L includes two layers, but is not limited thereto and may include three or more layers.

After forming the ground layer GND_L by a deposition process, etching may be performed to remove partial regions of the ground layer GND_L. In more detail, a post hole 600 may be formed by removing a region of the ground layer GND_L corresponding to the upper surface of the conductive post 300. In an embodiment, the plurality of conductive posts 300 are arranged in a column at each of the left and right, but if the plurality of conductive posts 300 are arranged in a plurality of columns, the plurality of post holes 600 may be provided to correspond to the plurality of conductive posts 300. Gas holes 500 may be formed by removing partial regions of the ground layer GND_L. In an embodiment, although gas holes 500 are provided in three columns in the cross-sectional view of FIG. 16, gas holes 500 of three or more columns may be provided as shown in FIG. 7, and the number, thickness, and the like of gas holes 500 are not limited thereto.

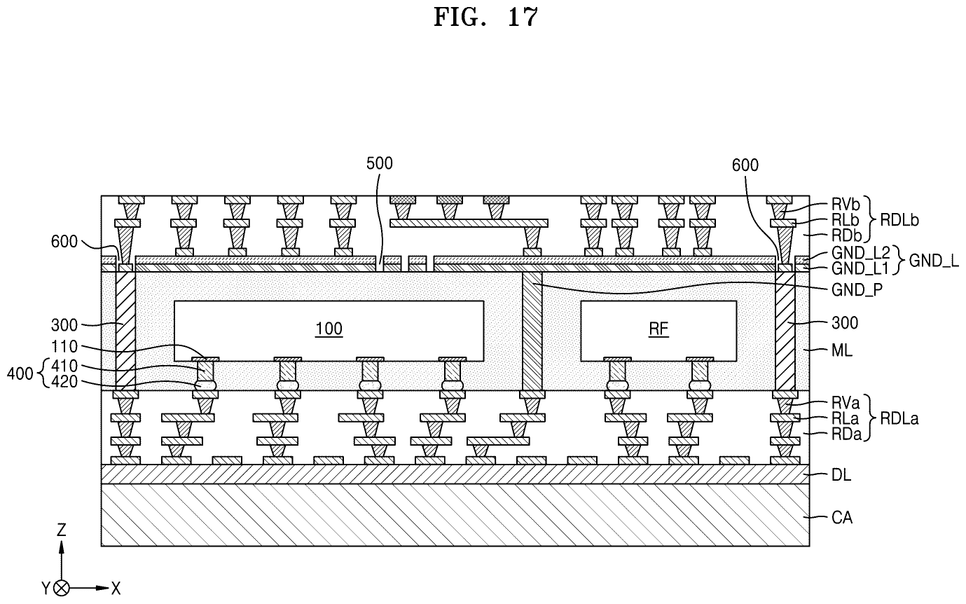

Referring to FIG. 17, the upper redistribution structure RDLb may be formed on the molding layer ML, the plurality of conductive posts 300, the ground post GND_P, and the ground layer GND_L.

The upper surface of the conductive post 300 may be in direct contact with the upper redistribution structure RDLb by removing a region of the ground layer GND_L corresponding to the conductive post 300. For example, the conductive post 300 may be electrically connected to the upper redistribution structure RDLb. Accordingly, the upper redistribution structure RDLb may be electrically connected to the lower redistribution structure RDLa via the conductive post 300.

The upper redistribution structure RDLb may include the upper wiring layer RLb, the upper vertical via RVb vertically connected to the upper wiring layer RLb, the ground wiring layer GND_RLb in contact with at least some of the plurality of upper vertical vias RVb, and the upper insulating layer RDb surrounding the upper wiring layer RLb and the upper vertical via RVb.

Herein, according to a process of forming the upper vertical via RVb, the upper vertical via RVb may be formed to have a horizontal area decreasing toward the first semiconductor chip 100.

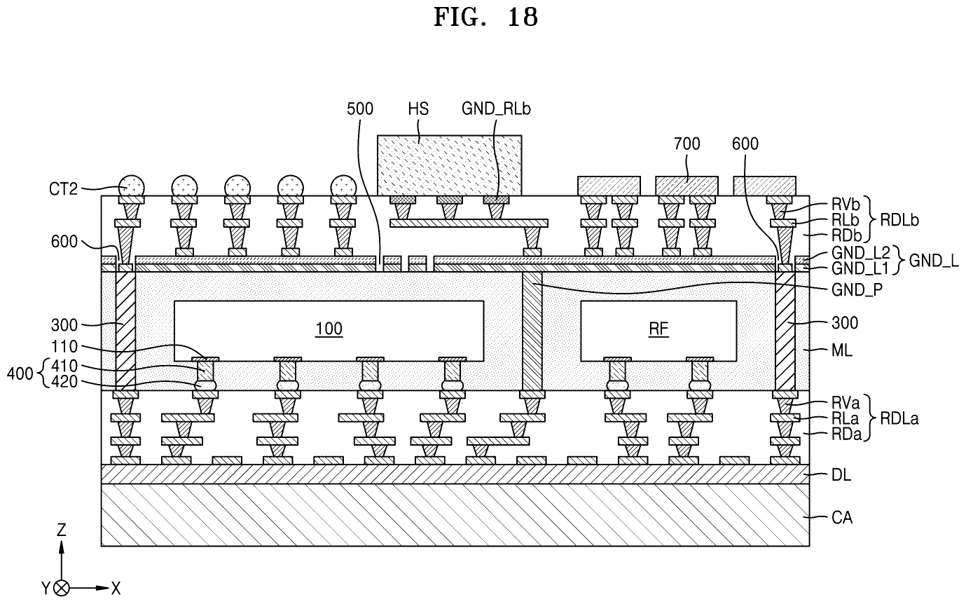

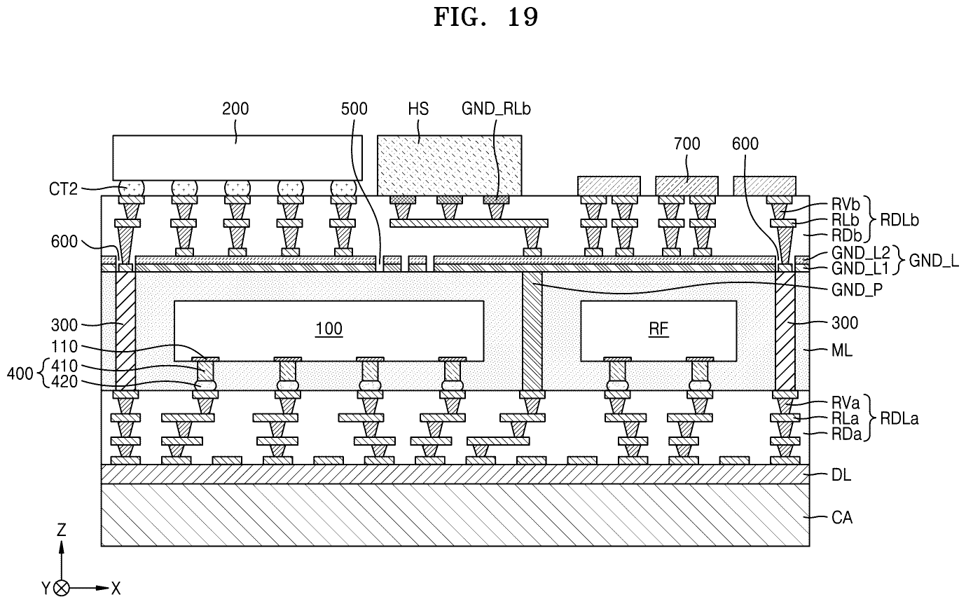

Referring to FIGS. 18 and 19, the plurality of internal connection terminals CT2 may be formed on the upper redistribution structure RDLb and the second semiconductor chip 200 may be mounted on the plurality of internal connection terminals CT2.

The second semiconductor chip 200 may be mounted on the upper redistribution structure RDLb such that the active surface of the second semiconductor chip 200 faces the upper redistribution structure RDLb. In this case, the second semiconductor chip 200 may be electrically connected to the upper redistribution structure RDLb via the plurality of internal connection terminals CT2 formed between the second semiconductor chip 200 and the upper redistribution structure RDLb.

The second semiconductor chip 200 may be electrically connected to the lower redistribution structure RDLa via the plurality of internal connection terminals CT2, the upper redistribution structure RDLb, and the conductive post 300. However, a method of mounting the second semiconductor chip 200 on the upper redistribution structure RDLb is not limited thereto.

The heat spreader HS may be mounted on the upper redistribution structure RDLb so as to be separated from the second semiconductor chip 200 in the first horizontal direction X. In more detail, the heat spreader HS may be in direct contact with and electrically connected to the ground wiring layer GND_RLb included in the upper redistribution structure RDLb.

An antenna 700 may be mounted on the upper redistribution structure RDLb so as to be separated from the heat spreader HS in the first horizontal direction X. In more detail, the plurality of antennas 700 may be separated from each other and at least some of the plurality of antennas 700 may be electrically connected to the lower redistribution structure RDLa via the upper redistribution structure RDLb and the conductive post 300. However, a method of mounting the plurality of antennas 700 on the upper redistribution structure RDLb is not limited thereto.

Referring to FIGS. 1 and 19, the semiconductor package 1 shown in FIG. 1 may be obtained by removing the carrier substrate CA and the adhesive insulating layer DL and forming the plurality of external connection terminals CT1 on the lower surface of the lower redistribution structure RDLa in FIG. 19.

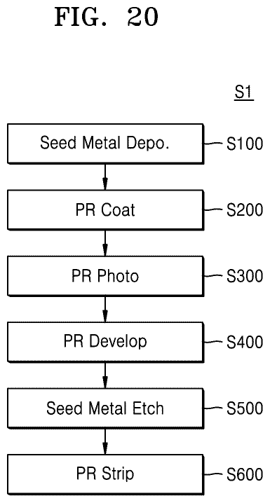

FIG. 20 is a flowchart illustrating a process S1 of generating an electromagnetic interference (EMI) shield ground layer.

Referring to FIG. 20, the process S1 of generating an EMI shield ground layer may include operation S100 of depositing a seed metal on the molding layer ML (see FIG. 1) and operation S200 of coating the seed metal with a photoresist (PR). A material of the coated PR may include a positive PR from which a photosensitive portion is removed during development or a negative PR from which a non-photosensitive portion is removed during development. The process S1 of generating an EMI shield ground layer may further include photo operation S300 of exposing a coating layer to light after the PR coating. Photo operation S300 may include at least one of a contact scheme of directly putting a mask on a substrate, a proximity scheme of separating a mask from the substrate, a projection scheme of forming a mask to be smaller than the substrate, separating the mask from the substrate, and then projecting light toward the substrate through a lens, and/or an immersion scheme of arranging a lens between the substrate and a mask and filling a liquid between the lens and the substrate, but is not limited thereto.

The process S1 of generating an EMI shield ground layer may further include development operation S400 of removing the photosensitive portion or the non-photosensitive portion after photo operation S300.

In addition, the process S1 of generating an EMI shield ground layer may further include operation S500 of etching portions of the seed metal to form the plurality of post holes 600 (see FIG. 1) and the plurality of gas holes 500 (see FIG. 1) and strip operation S600 of removing an unnecessary PR portion (or unnecessary PR portions) after the etching.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts has been particularly shown and described with reference to embodiments thereof, it will be understood that various changes in form and details may be made therein without departing from the spirit and scope of the following claims.

What is claimed is:

1. A semiconductor package comprising:
a lower redistribution structure;
a plurality of conductive posts on an upper surface of the lower redistribution structure, the plurality of conductive posts including a conductive post;
a first semiconductor chip on the upper surface of the lower redistribution structure, the first semiconductor chip being separated from the conductive post in a direction parallel to the upper surface of the lower redistribution structure;
a radio frequency chip on the upper surface of the lower redistribution structure and separated from the first semiconductor chip in the direction parallel to the upper surface of the lower redistribution structure;
a ground post between the first semiconductor chip and the radio frequency chip, the ground post configured to shield against an electromagnetic wave generated from the radio frequency chip;
a molding layer covering the upper surface of the lower redistribution structure and surrounding the plurality of conductive posts, the first semiconductor chip, the radio frequency chip, and the ground post; and
a ground layer on an upper surface of the molding layer and in contact with an upper surface of the ground post.

2. The semiconductor package of claim 1, wherein
the ground layer includes a first ground layer and a second ground layer on an upper surface of the first ground layer,
the ground layer has a plurality of gas holes and a plurality of post holes penetrating the ground layer in a vertical direction, and
the plurality of post holes correspond to upper surfaces of the plurality of conductive posts.

3. The semiconductor package of claim 1, further comprising:
an upper redistribution structure comprising a plurality of upper vertical vias on the molding layer and a plurality of upper wiring layers in contact with at least one of the plurality of upper vertical vias; and
a ground wiring layer in contact with at least one of the plurality of upper vertical vias.

4. The semiconductor package of claim 3, further comprising:
a heat spreader on an upper surface of the upper redistribution structure, wherein
the heat spreader is in contact with the ground wiring layer.

5. The semiconductor package of claim 3, further comprising:
a plurality of internal connection terminals on an upper surface of the upper redistribution structure; and
a second semiconductor chip in contact with the plurality of internal connection terminals and electrically connected to the first semiconductor chip.

6. The semiconductor package of claim 3, further comprising:
a plurality of antennas on an upper surface of the upper redistribution structure and electrically connected to the radio frequency chip.

7. The semiconductor package of claim 1, wherein a thickness of the ground layer is 10 μm or less.

8. The semiconductor package of claim 2, wherein
the first ground layer and the second ground layer each include a metal, and
a material of the first ground layer is different from a material of the second ground layer.

9. The semiconductor package of claim 1, further comprising:
a plurality of chip connection terminals between the first semiconductor chip and the lower redistribution structure and between the radio frequency chip and the lower redistribution structure.

10. The semiconductor package of claim 9, wherein each of the plurality of chip connection terminals comprises:
a conductive cap on the upper surface of the lower redistribution structure and electrically connected to the lower redistribution structure; and
a lower filler on an upper surface of the conductive cap and electrically connected to the conductive cap.

11. The semiconductor package of claim 1, further comprising:
a plurality of external connection terminals on a lower surface of the lower redistribution structure.

12. A semiconductor package comprising:
a lower redistribution structure;
a plurality of conductive posts on an upper surface of the lower redistribution structure, the plurality of conductive posts including a conductive post;
a first semiconductor chip on the upper surface of the lower redistribution structure and separated from the conductive post in a direction parallel to the upper surface of the lower redistribution structure;
a radio frequency chip on the upper surface of the lower redistribution structure and separated from the first semiconductor chip in the direction parallel to the upper surface of the lower redistribution structure;
a ground post between the first semiconductor chip and the radio frequency chip, the ground post configured to shield against an electromagnetic wave generated from the radio frequency chip;
a molding layer covering the upper surface of the lower redistribution structure and surrounding the plurality of conductive posts, the first semiconductor chip, the radio frequency chip, and the ground post;
a ground layer on an upper surface of the molding layer and in contact with an upper surface of the ground post;
an upper redistribution structure including a plurality of upper vertical vias on the molding layer and a plurality of upper wiring layers in contact with at least one of the plurality of upper vertical vias;
a ground wiring layer in contact with at least one of the plurality of upper vertical vias; and
a heat spreader on an upper surface of the upper redistribution structure and in contact with the ground wiring layer, wherein
the ground layer includes a first ground layer and a second ground layer on an upper surface of the first ground layer,
the ground layer has a plurality of gas holes and a plurality of post holes penetrating the ground layer in a vertical direction, and
the plurality of post holes correspond to upper surfaces of the plurality of conductive posts.

13. The semiconductor package of claim 12, wherein the ground post, the ground layer, the ground wiring layer, and the heat spreader are electrically connected to each other.

14. The semiconductor package of claim 12, further comprising:
a plurality of internal connection terminals on the upper surface of the upper redistribution structure; and
a second semiconductor chip in contact with the plurality of internal connection terminals and electrically connected to the first semiconductor chip.

15. The semiconductor package of claim 12, further comprising:
a plurality of antennas on the upper surface of the upper redistribution structure and electrically connected to the radio frequency chip.

16. The semiconductor package of claim 12, wherein
a thickness of the ground layer is 10 μm or less,
the first ground layer and the second ground layer include a metal, and
a material the first ground layer is different from a material of the second ground layer.

17. The semiconductor package of claim 12, further comprising:
a plurality of chip connection terminals between the first semiconductor chip and the lower redistribution structure and between the radio frequency chip and the lower redistribution structure, wherein
each of the plurality of chip connection terminals comprises a conductive cap and a lower filler,
the conductive cap is on the upper surface of the lower redistribution structure and electrically connected to the lower redistribution structure, and
the lower filler is on an upper surface of the conductive cap and electrically connected to the conductive cap.

18. The semiconductor package of claim 12, further comprising:
a plurality of external connection terminals on a lower surface of the lower redistribution structure.

19. A semiconductor package comprising:
a lower redistribution structure;
a plurality of conductive posts on an upper surface of the lower redistribution structure, the plurality of conductive posts including a conductive post;
a first semiconductor chip on the upper surface of the lower redistribution structure and separated from the conductive post in a direction parallel to the upper surface of the lower redistribution structure;
a radio frequency chip on the upper surface of the lower redistribution structure and separated from the first semiconductor chip in the direction parallel to the upper surface of the lower redistribution structure;
a ground post between the first semiconductor chip and the radio frequency chip, the ground post configured to shield against an electromagnetic wave generated from the radio frequency chip;
a molding layer covering the upper surface of the lower redistribution structure and surrounding the plurality of conductive posts, the first semiconductor chip, the radio frequency chip, and the ground post;
a ground layer on an upper surface of the molding layer and in contact with an upper surface of the ground post;
an upper redistribution structure including a plurality of upper vertical vias on the molding layer and a plurality of upper wiring layers in contact with at least one of the plurality of upper vertical vias;
a ground wiring layer in contact with at least one of the plurality of upper vertical vias;
a heat spreader on an upper surface of the upper redistribution structure and in contact with the ground wiring layer;
a plurality of internal connection terminals on the upper surface of the upper redistribution structure;
a second semiconductor chip in contact with the plurality of internal connection terminals and electrically connected to the first semiconductor chip; and
a plurality of antennas on the upper surface of the upper redistribution structure and electrically connected to the radio frequency chip, wherein
the ground layer includes a first ground layer and a second ground layer on an upper surface of the first ground layer,
the ground layer has a plurality of gas holes and a plurality of post holes penetrating the ground layer in a vertical direction,
the plurality of post holes correspond to upper surfaces of the plurality of conductive posts,
the ground post, the ground layer, the ground wiring layer, and the heat spreader are electrically connected to each other,
a thickness of the ground layer is 10 μm or less,
the first ground layer and the second ground layer include a metal, and
a material of the first ground layer is different from a material of the second ground layer.

20. The semiconductor package of claim 19, further comprising:
a plurality of chip connection terminals between the first semiconductor chip and the lower redistribution structure and between the radio frequency chip and the lower redistribution structure, wherein
each of the plurality of chip connection terminals comprises a conductive cap an a lower filler,
the conductive cap is on the upper surface of the lower redistribution structure and electrically connected to the lower redistribution structure, and
the lower filler on an upper surface of the conductive cap and electrically connected to the conductive cap.
